(19) United States
(12) Patent Application Publication
(10) Pub. No.: US 2026/0047420 A1
(43) Pub. Date: Feb. 12, 2026

(54) HIGH TEMPERATURE METALLIZATION

(71) Applicant: 3D Glass Solutions, Inc., Albuquerque, NM (US)

(72) Inventors: Timothy A. Gort, Rio Rancho, NM (US); Jeb H. Flemming, Albuquerque, NM (US); Irma Rocio Vazquez Hernandez, Albuquerque, NM (US)

(21) Appl. No.: 19/273,472

(22) Filed: Jul. 18, 2025

Related U.S. Application Data
(60) Provisional application No. 63/680,639, filed on Aug. 8, 2024.

(51) Int. Cl. H01L 23/532; H01L 21/768; H01L 23/522; H01L 23/528

(52) U.S. Cl. CPC H01L 23/53238; H01L 21/7685; H01L 23/5228; H01L 23/5283; H01L 23/53252

(57) ABSTRACT

Provided herein is a high temperature metallization structure with a refractory diffusion barrier for high-speed computing, RF, High Temperature Controls, and mmWave electronics and components.

A printed circuit board 2, a pure white 1, and a printed circuit board formed by transferring an interlayer conductor connecting projection formed by plating to a temporary circuit holding material to a true circuit holding material.

2, a printed circuit board which is formed by transferring a 4 body pattern formed by plating to a temporary circuit holding material and a projection for connecting an interlayer conductor to a true circuit holding material.

The **** circuit board according to claim 3, wherein a plurality of said printed circuit boards are stacked on one another in the form of a stack of printed circuit boards in the form of a stack of circuit boards according to claim 2.

### 3. DETAILED DESCRIPTION

The present invention relates to an improvement in a printed circuit board used in an electronic apparatus for communication.

Conventionally, a ** formed by etching a pattern on a printed board using an organic insulating material is processed by a few tens of thousands of times, a plurality of layers are formed, then a hole is machined, a plating is applied on an inner surface of the hole, a conductor is formed, and an electrical connection is made between conductors between layers.

In addition, a ** electrically conductive paste is printed on a substrate using a printed circuit board, and a pattern and a through-hole are formed by printing a conductive paste using a paste, or a circuit is printed by inserting a metal into the through-hole.

In such a printed circuit board, nz is inferior to that formed by a critical plating method in which a pattern is formed by a ** method or a printing method.

When the insulating material for the ** machine is used as a substrate, a value set hole hole machining for the through holes after the multilayer is made by a **, and a long pattern which is formed of a conductive paste and is formed of a conductive paste and a large electric resistance of a magic pattern is obtained by a conductive paste and a large electric resistance of a magic pattern is obtained is obtained by using a ceramic on a substrate.

The present invention has been devised to remedy these drawbacks.

For this reason, in the printed circuit board of the present invention, 1—* * * *, which is formed by plating on an anti-circuit holding material in advance, and which is formed by transferring a projection for connecting the next layer conductor, a conductor pattern, and an interlayer conductor, to a true circuit holding material, is defined as 0—* * .

Based on an accompanying drawing, it describes in details per Example of the present invention below.

FIG. 1111 is an explanatory view of a manufacturing process of a printed circuit board having a conductor pattern and a protrusion for an interlayer conductor IMf & in FIG. 10.

Referring to FIG. 1, a temporary * circuit holding member 1 is prepared as shown in FIG. 1.

The temporary circuit holding material 1 is an insulating plate or a metallic plate, and is subjected to ** electroless plating t in case of an insulating plate.

Next, a * photoresist 2 is deposited on the temporary circuit holding material 1 as shown in FIG. 2.

Next, the artwork film is placed on top of it, and a portion 4 of forming a * pattern as shown in FIG. 3 and a portion 5 of forming a projection for connecting the interlayer conductor are removed to remove a portion of the portion where the pattern is to be formed.

Next, as shown in FIG. 4, the * photoresist is removed and an electrolytic plating 6t is applied to the fc portion.

Then, as shown in an IE 5 diagram, a * and a photoresist 7′ ik are deposited on this. Next, an artwork film is placed on the photoresist 7 to leave an exposure pole, and a resist of a portion 8 for forming a projection for integral connection between * layers as shown in FIG. 886 is removed.

Next, as shown in FIG. 7, an electrolytic plating 9 is applied to a portion of the Lycium chinense from which a resist of a is removed. *.

Next, the photoresist 7 is removed to obtain a temporary rotation-path holding member 1 in which a conductor pattern 10 as shown in FIG. 8 and a projection 11 for connecting an interlayer connection are formed.

Next, when the temporary circuit holding material 1 is pressed onto the true circuit holding material by placing the pattern 10 and the projection 11 for connecting the interlayer conductor on the true circuit holding material, as shown in FIG. 19, the * pattern and the projection 11 for connecting the interlayer conductor are pressed into the true circuit holding material 12 and embedded.

In this case, the projection 11 for connecting the interlayer conductor acts as a punch and pierces the true circuit holding material 12.

Finally, when the temporary circuit-holding material 1 t—chemical or mechanical is removed, the * conductor pattern 10 and the N-conductor connecting projection 11 are transferred as shown in FIG. 10 to obtain a printed circuit board engineer 3 of the 9 invention.

As the true circuit holding material 12, a green ceramic, a resin insulation, a spade plate, or the like is used.

In addition, when only the projection for connecting the inter-node conductor is transferred and the pattern is formed separately, the pattern forming step from the ** of the above described to FIG. 2 to FIG. 4 may be omitted from the. * ** .

Next, as shown in FIG. 11 of a plurality of printed circuit boards 13 formed in this way, a multilayer printed board 14 can be obtained by forming a * as shown in FIG. 1. In this case, as shown in FIG. 1, for example, a projection 11 for connection between * layers and a conductor 15 for bonding between 11′ can be pressed and heated to be heated.

If a true circuit holding material 12 is ceramic as the conductor 15 for bonding, a chain ring having a melting point of about 800° C. or a copper putty is used, and when the true circuit holding material 12 is a resin, a brazing material having a melting point of about 200° C., such as solder or silver containing silver, may be used.

As described above, the printed circuit board by un-inventing is the projection for the conductor connection between layers to a temporary circuit holding material Or it forms with plating for a conductive pattern and the conductor connection between 14 on a projection, and this is transferred to a true circuit holding material, and since resistance of a conductive pattern can be performed small, the printed circuit board of a large-sized ceramic substrate is obtained.

In addition, since fine holes for through-holes are not required in the true circuit holding material in advance, it is possible to reduce the number of manufacturing steps and to eliminate the ** property of drilling.

### 4. Brief Explanation of the Drawings

FIGS. 1 to 10 are views of a printed circuit board according to an embodiment of the present invention, and FIG. 11 is a cross-sectional view of a printed circuit board of another embodiment according to the present invention.

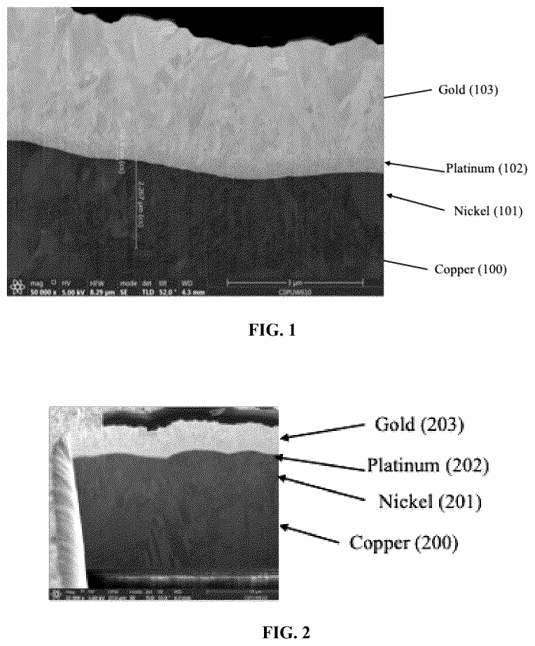

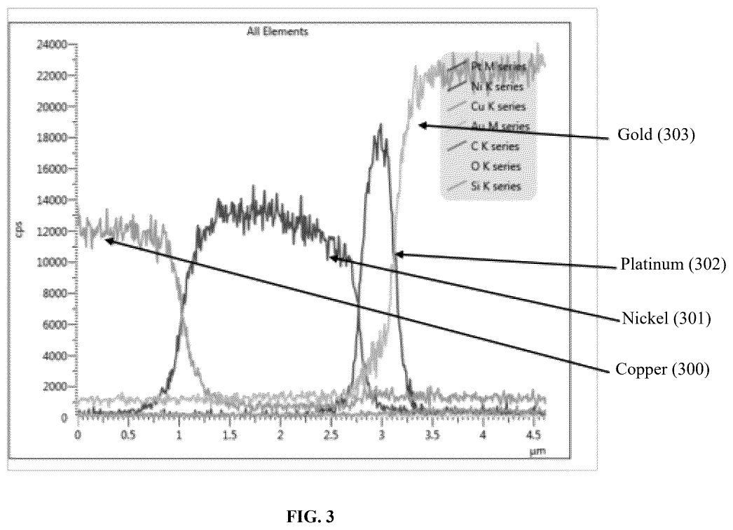

1. temporary circuit holding material, 2. “7. photoresist, conductive pattern, projecting/12. true circuit holding material for connecting 11. interlayer conductor”, 13. printed circuit board, 14. multilayer printed circuit board, 15. bonding conductor.

Patent Application Attorney Docket No. 1), Attorney docket No. Nishidate Sum Attorney, Inc., Attorney Docket No. Sumk. **

What is claimed is:

1. An electrode or electronic structure for high-speed computing, radio frequency (RF), high temperature control, and millimeter microwave (mmWave) electronics, comprising:
a substrate having a conductor;
a refractory conductive diffusion barrier within the conductor that reduces or eliminates current crowding along a length and/or a skin of the conductor.

2. The electrode or electronic structure of claim 1, wherein the refractory conductive diffusion barrier is between 0.05 μm and 4 μm thick.

3. The electrode or electronic structure of claim 1, wherein the conductor comprises a bend or corner that is at a 15, 20, 30, 40, 50, 60, 70, 80, or 90 degree or a path that narrows in at least a portion of the conductor.

4. The electrode or electronic structure of claim 1, wherein the refractory conductive diffusion barrier comprises at least one of: Tantalum Nitride (TaN); Titanium Nitride (TiN); Tungsten Nitride (WN); Cobalt Tungsten Phosphide (CoWP), Ruthenium (Ru), or Platinum (Pt).

5. The electrode or electronic structure of claim 1, wherein the refractory conductive diffusion barrier is Platinum (Pt).

6. The electrode or electronic structure of claim 1, wherein the electrode or electronic structure is selected from at least one of: copper, nickel, platinum, and gold.

7. The electrode or electronic structure of claim 1, wherein the electrode or electronic structure is copper, nickel, platinum and gold.

8. The electrode or electronic structure of claim 1, wherein the electrode or electronic structure is, in order, copper, nickel, platinum, and gold.

9. The electrode or electronic structure of claim 7, wherein the copper is between about 0.5 μm to 20 μm thick, or is 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick.

10. The electrode or electronic structure of claim 7, wherein the nickel is between about 0.5 μm to 4 μm thick, or is 0.5, 0.6, 0.7, 0.8, 0.9, 1, 2, 3, or 4 μm thick.

11. The electrode or electronic structure of claim 7, wherein the platinum is between about 0.05 μm to 4 μm thick, or is 0.05, 0.06, 0.07, 0.08, 0.09, 0.1, 0.2, 0.3, 0.4, 0.5, 0.6, 0.7, 0.8, 0.9, 1, or 2 μm thick.

12. The electrode or electronic structure of claim 7, wherein the gold is between about 0.5 μm to 5 μm thick, or is 0.5, 0.6, 0.7, 0.8, 0.9, 1, 2, 3, 4, or 5 μm thick.

13. The electrode or electronic structure of claim 11, wherein the refractory conductive diffusion barrier is platinum and is about 0.5 μm.

14. The electrode or electronic structure of claim 1, wherein there is no diffusion of the gold across the refractory conductive diffusion barrier or into a nickel layer when the electrode or electronic structure are annealed at 600° C. for 20 minutes.

15. A method of making an electrode or electronic structure for high-speed computing, radio frequency (RF), high temperature control, and millimeter microwave (mmWave) electronics, comprising:
depositing a substrate having a conductor;
forming a refractory conductive diffusion barrier within the conductor that reduces or eliminates current crowding along a length and/or a skin of the conductor.

16. The method of claim 15, wherein the refractory conductive diffusion layer is between 0.05 μm and 4 μm thick.

17. The method of claim 15, wherein the conductor comprises a bend or corner that is at a 15, 20, 30, 40, 50, 60, 70, 80, or 90 degree or a path that narrows in a portion of the conductor.

18. The method of claim 15, wherein the refractory conductive diffusion barrier comprises at least one of: Tantalum Nitride (TaN); Titanium Nitride (TiN); Tungsten Nitride (WN); Cobalt Tungsten Phosphide (CoWP), Ruthenium (Ru), or Platinum (Pt).

19. The method of claim 15, wherein the refractory conductive diffusion barrier is Platinum (Pt).

20. The method of claim 15, wherein the electrode or electronic structure is selected from at least one of: copper, nickel, platinum and gold.

21. The method of claim 15, wherein the electrode or electronic structure is copper, nickel, platinum and gold.

22. The method of claim 15, wherein the electrode or electronic structure is, in order, copper, nickel, platinum, and gold.

23. The method of claim 21, wherein the copper is between about 0.5 μm to 20 μm thick, or is 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick.

24. The method of claim 21, wherein the nickel is between about 0.5 μm to 4 μm thick, or is 0.5, 0.6, 0.7, 0.8, 0.9, 1, 2, 3, or 4 μm thick.

25. The method of claim 21, wherein the platinum is between about 0.05 μm to 4 μm thick, or is 0.05, 0.06, 0.07, 0.08, 0.09, 0.1, 0.2, 0.3, 0.4, 0.5, 0.6, 0.7, 0.8, 0.9, 1, or 2 μm thick.

26. The method of claim 21, wherein the gold is between about 0.5 μm to 5 μm thick, or is 0.5, 0.6, 0.7, 0.8, 0.9, 1, 2, 3, 4, or 5 μm thick.

27. The method of claim 21, wherein the platinum diffusion barrier is 0.5 μm.

28. The method of claim 15, wherein there is no diffusion across the refractory conductive diffusion layer when the electrode or electronic structure are annealed at 600° C. for 20 minutes.

29. The method of claim 15, wherein the refractory conductive diffusion barrier is formed or deposited by at least one of: Physical Vapor Deposition (PVD); Chemical Vapor Deposition (CVD), Plasma-enhanced CVD (PECVD), low-pressure CVD (LPCVD), Atomic Layer Deposition (ALD), and/or an electrochemical process.
